(19) United States
(12) Patent Application Publication
(10) Pub. No.: US 2019/0393673 A1
(43) Pub. Date: Dec. 26, 2019

(54) LASER ASSEMBLY

(71) Applicant: Becton, Dickinson and Company, Franklin Lakes, NJ (US)

(72) Inventors: Jianying Cao, San Jose, CA (US); Dennis Rey, Livermore, CA (US); Qing Shao, Pleasanton, CA (US)

(21) Appl. No.: 16/363,916

(22) Filed: Mar. 25, 2019

Related U.S. Application Data
(60) Provisional application No. 62/688,332, filed on Jun. 21, 2018.

(51) Int. Cl. H01S 5/024; G01N 15/14

(52) U.S. Cl. CPC H01S 5/02415; G01N 2015/0065; G01N 15/1404

(57) ABSTRACT

Laser assemblies are provided. Aspects of the laser assemblies according to certain embodiments include a laser, a thermoelectric cooler in contact with a bottom surface of the laser and a heat dissipation component in contact with a bottom surface of the thermoelectric cooler. Optical decks having a substrate and a laser assembly, e.g. as described above, are also provided. Methods and systems for irradiating a sample in a flow stream with the laser assembly are also provided. Aspects further include kits having a diode laser, a thermoelectric cooler and a heat dissipation component.

### INTRODUCTION

Flow cytometry is a technique used to characterize and often times sort biological material, such as cells of a blood sample or particles of interest in another type of biological or chemical sample. The flow cytometer transports the particles (including cells) in the fluid sample as a cell stream to a flow cell, while also directing the sheath fluid to the flow cell. To characterize the components in the flow stream, light must impinge on the flow stream and be collected. Light sources in flow cytometers can vary from broad spectrum lamps, light emitting diodes as well as single wavelength lasers. The light source is aligned with the flow stream and an optical response from the illuminated particles is collected and quantified.

Lasers are often used in flow cytometry because of their spectral specificity, intensity and well-controlled alignment with the flow stream. Laser beam pointing remains stable when heat from the laser is properly controlled and thermal energy released and heat generated by laser electronics do not interfere with flow stream irradiation (e.g., alignment, fluctuations in laser power, etc.).

### SUMMARY

Laser assemblies are provided. Aspects of the laser assemblies according to certain embodiments include a laser, a thermoelectric cooler in contact with a bottom surface of the laser and a heat dissipation component in contact with a bottom surface of the thermoelectric cooler. Optical decks having a substrate and a laser assembly, e.g. as described above, are also provided. Methods and systems for irradiating a sample in a flow stream with the laser assembly are also provided. Aspects further include kits having a diode laser, a thermoelectric cooler and a heat dissipation component.

In embodiments, the laser assembly includes a laser. In some embodiments, the laser is a pulsed laser. In other embodiments, the laser is a continuous wave laser. The laser may be a diode laser, a gas laser, a solid-state laser, a dye laser or a metal-vapor laser. The laser assembly may include 1 or more lasers, such as 2 or more lasers, such as 3 or more lasers and including 4 or more lasers. In certain embodiments, the laser only includes temperature sensitive components such as the laser diode and a collimating lens to minimize the thermal mass released to the thermoelectric cooler. In these embodiments, electronic components, optical components (e.g., beam shapers, light taping components, etc.) as well as laser power monitors (e.g., feedback photodiode) may be separated from the laser. In certain instances, the laser consists of a laser diode and a collimating lens.

The thermoelectric cooler is positioned in contact with a bottom surface of the laser. In some embodiments, only a part of the bottom surface of the laser is in contact with the thermoelectric cooler. In other embodiments, the entire bottom surface of the laser is in contact with the thermoelectric cooler. The thermoelectric cooler may be a Peltier heat pump.

The heat dissipation component is in contact with a bottom surface of the thermoelectric cooler. In some embodiments, the heat dissipation component includes a heat transfer block and a heat dissipation fin. In other embodiments, the heat dissipation component includes a heat transfer block and a plurality of heat dissipation fins. In certain embodiments, the heat dissipation component includes a first heat transfer block and a second heat transfer block. In some instances, heat from the thermoelectric cooler is configured to be symmetrically dissipated to the first heat transfer block and the second heat transfer block. In these embodiments, the heat dissipation component may be symmetrical across a vertical plane. In other embodiments, the heat dissipation component may be axially symmetrical. The heat dissipation component may also include one or more cutouts, e.g., cutouts that dissipate heat by thermal expansion. In some embodiments, the heat dissipation component is formed from a ceramic material. In other embodiments, the heat dissipation component is formed from a metal material.

The present disclosure also describes an optical deck having a laser assembly mounted to a top surface of a substrate. In some instances, the substrate is a printed circuit board (PCB). In some embodiments, at least a part of the bottom surface of the heat dissipation component is in contact with substrate surface. In other embodiments, the bottom surface of the heat dissipation component is not in physical contact with the substrate. In these embodiments, the laser assembly may be mounted to the surface of the substrate with one or more mounting pads. In some instances, the mounting pads are positioned between the bottom surface of the heat dissipation component and the substrate surface. The mounting pads are, in some instances, thermally insulating. In other instances, the mounting pads are electrically insulating. In still other instances, the mounting pads are thermally insulating and electrically insulating.

Aspects of the present disclosure also include a flow cytometer having a flow cell configured to propagate a sample in a flow stream, a sensor for detecting light signals from the flow stream and a laser assembly having a laser configured to irradiate the sample in the flow stream. In certain embodiments, the sample in the flow stream includes cells and the flow cytometer is configured for characterizing one or more cells or extracellular vesicles of the cells in the sample. Characterizing the extracellular vesicles of the cells may include identifying the type of extracellular vesicles in the cells and/or determining the size of the extracellular vesicles in the cells. Photosensors in the flow cytometer are configured for measuring light from a sample in a flow stream. The sensor may be configured to detect forward scattered light, side scattered light, transmitted light, emitted light or a combination thereof. Light signals may be detected continuously or in periodic intervals. In some embodiments, the sensor is a position sensing detector, such as a quadrant photodiode or a photodiode array composed of a plurality of detectors. Among the plurality of detectors may be one or more solid-state detectors, such as avalanche photodiodes. In certain instances, the detector array is composed of a plurality of solid state detectors, such as an array of avalanche photodiodes.

Aspects of the present disclosure also include methods for irradiating a sample in a flow stream with an output beam from the laser assembly. Methods according to certain embodiments include irradiating a sample in a flow stream with a beam of laser light and detecting light from the flow stream at one or more wavelengths. Light from a sample in the flow stream may be detected by forward scattered light, side scattered light, transmitted light, emitted light or a combination thereof. In certain embodiments, methods include multi-photon counting of photons from light from the sample in the flow stream. In some embodiments, light from the flow stream is measured at discrete wavelengths from 200 nm to 1200 nm, such as for example at one or more wavelengths from 450 nm, 518 nm, 519 nm, 561 nm, 578 nm, 605 nm, 607 nm, 617 nm 625 nm, 647 nm, 650 nm, 660 nm, 667 nm, 670 nm, 668 nm, 695 nm, 710 nm, 723 nm, 780 nm and 785 nm. In other embodiments, light from the flow stream is measured across wavelengths of from 200 nm to 1200 nm, such as for example to generate a spectrum of the light from 200 nm to 1200 nm. Methods may also include characterizing one or more particles (e.g., cells) in the sample. In certain instances, methods further include sorting particles (e.g., cells) from the sample into two or more sample collection containers in response to the detected light. In these embodiments, the particles may be sorted with a droplet deflector configured to apply a deflection force to droplets of the flow stream.

Kits including one or more components of the subject laser assemblies are also provided. Kits according to certain embodiments include one or more diode lasers, a thermoelectric cooler and a heat dissipation component. Kits may also include one or more thermal insulation pads configured to be affixed to a bottom surface of the heat dissipation component as well as one or more heat dissipation fins which may be reversibly attached to the heat dissipation component. In certain embodiments, kits include a substrate (e.g., a PCB) for mounting the laser assembly. Kits may also include one or more optical adjustment components such as a focusing lens, a collimator, beam splitter, a wavelength separator or a combination thereof. In some instances, kits also include a laser power monitor, for example to assess the stability of the laser output power from the laser assembly.

### BRIEF DESCRIPTION OF THE FIGURE

The invention may be best understood from the following detailed description when read in conjunction with the accompanying drawing. Included in the drawing is the following FIGURE:

FIG. 1 depicts a laser assembly having a laser, a thermoelectric cooler and a heat dissipation component having a heat transfer block and heat dissipation fins according to certain embodiments.

### DETAILED DESCRIPTION

Laser assemblies are provided. Aspects of the laser assemblies according to certain embodiments include a laser, a thermoelectric cooler in contact with a bottom surface of the laser and a heat dissipation component in contact with a bottom surface of the thermoelectric cooler. Optical decks having a substrate and a laser assembly, e.g. as described above, are also provided. Methods and systems for irradiating a sample in a flow stream with the laser assembly are also provided. Aspects further include kits having a diode laser, a thermoelectric cooler and a heat dissipation component.

Before the present invention is described in greater detail, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Certain ranges are presented herein with numerical values being preceded by the term “about.” The term “about” is used herein to provide literal support for the exact number that it precedes, as well as a number that is near to or approximately the number that the term precedes. In determining whether a number is near to or approximately a specifically recited number, the near or approximating unrecited number may be a number which, in the context in which it is presented, provides the substantial equivalent of the specifically recited number.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

While the apparatus and method has or will be described for the sake of grammatical fluidity with functional explanations, it is to be expressly understood that the claims, unless expressly formulated under 35 U.S.C. § 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 U.S.C. § 112 are to be accorded full statutory equivalents under 35 U.S.C. § 112.

As summarized above, the present disclosure provides a laser assembly. In further describing embodiments of the disclosure, laser assemblies having a laser, a thermoelectric cooler and a heat dissipation component are first described in greater detail. Next, optical decks having a mounted laser assembly on a substrate (e.g., PCB) are described. Flow cytometer systems and methods for irradiating a sample in a flow stream with an output beam from a laser assembly are also provided. Kits having a diode laser, a thermoelectric cooler and a heat dissipation component are described.

### Laser Assembly

Aspects of the present disclosure include a laser assembly. Laser assemblies according to certain embodiments include a laser, a thermoelectric cooler in contact with a bottom surface of the laser and a heat dissipation component in contact with a bottom surface of the thermoelectric cooler. In embodiments, laser assemblies described herein reduce the amount of heat energy transferred or dissipated to adjacent components in a laser irradiation system, such as an optical interrogation component of a flow cytometer. For example, the subject laser assemblies are configured to reduce the amount of heat energy transferred to adjacent components by 10% or more, such as by 15% or more, such as by 25% or more, such as by 50% or more, such as by 75% or more, such as 90% or more, such as by 95% or more and including by 99% or more. In some embodiments, a laser assembly provides for reduced heat energy transfer sufficient to increase laser beam pointing stability. In other embodiments, a laser assembly provides for reduced heat energy transfer sufficient to reduce thermal drift by the laser beam. In yet other embodiments, a laser assembly provides for reduced heat energy transfer sufficient to reduce variability in laser power during operation, such as determined with a scanning slit profiler, a charge coupled device (CCD, such as an intensified charge coupled device, ICCD), a positioning sensor, power sensor (e.g., a thermopile power sensor), optical power sensor, energy meter, digital laser photometer, a laser diode detector, etc. In still other embodiments, heat energy from the laser assembly is isolated and is dissipated by the cooling components of the laser assembly without transfer to any adjacent components in the system. In certain embodiments, a laser assembly is configured to provide for one or more of: 1) increased laser beam pointing stability; 2) reduced thermal drift; 3) reduced variability in laser power during operation; and 4) heat dissipation by exhibiting symmetrical heat dissipation. As described in greater detail below, heat may, in some instances, be symmetrically dissipated across a vertical plane of a laser assembly. In other instances, heat dissipation is axially symmetrical (i.e., outward from an axis of the laser assembly).

In embodiments, the laser assembly includes one or more lasers, such as two or more lasers, such as 3 or more lasers, such as 4 or more lasers, such as 5 or more lasers, such as 6 or more lasers and including 10 or more lasers. Lasers of interest may include pulsed lasers or continuous wave lasers. The type and number of lasers may vary and may be a diode laser, a gas laser, such as a helium-neon laser, argon laser, krypton laser, xenon laser, nitrogen laser, CO₂ laser, CO laser, argon-fluorine (ArF) excimer laser, krypton-fluorine (KrF) excimer laser, xenon chlorine (XeCl) excimer laser or xenon-fluorine (XeF) excimer laser or a combination thereof. In others instances, laser assemblies of interest include a dye laser, such as a stilbene, coumarin or rhodamine laser. In yet other instances, the laser assembly includes a metal-vapor laser, such as a helium-cadmium (HeCd) laser, helium-mercury (HeHg) laser, helium-selenium (HeSe) laser, helium-silver (HeAg) laser, strontium laser, neon-copper (NeCu) laser, copper laser or gold laser and combinations thereof. In still other instances, the laser assembly includes a ruby laser, an Nd:YAG laser, NdCrYAG laser, Er:YAG laser, Nd:YLF laser, Nd:YVO₄ laser, Nd:YCa₄O(BO₃)₃ laser, Nd:YCOB laser, titanium sapphire laser, thulium YAG laser, ytterbium YAG laser, ytterbium₂O₃ laser or cerium doped lasers and combinations thereof. In still other instances, the laser assembly includes a semiconductor diode laser, optically pumped semiconductor laser (OPSL), or a frequency doubled- or frequency tripled implementation of any of the above mentioned lasers.

Depending on the desired wavelengths of light produced in the output laser beam (e.g., for use in irradiating a sample in a flow stream), each laser may have a specific wavelength that varies from 200 nm to 1500 nm, such as from 250 nm to 1250 nm, such as from 300 nm to 1000 nm, such as from 350 nm to 900 nm and including from 400 nm to 800 nm. The laser assembly may include any combination of types of lasers. For example, in some embodiments, the subject laser assembly includes an array of lasers, such as an array having one or more diode lasers, one or more gas lasers, one or more dye lasers and one or more solid-state lasers. In certain embodiments, a laser assembly of interest includes an array of continuous wave diode lasers.

In some embodiments, the laser in the laser assembly is configured to minimize the heat energy generated by the laser (e.g., the laser head), such as by containing only the required components for generating a suitable laser beam. In some instances, the laser includes a housing containing only a laser diode. In other instances, the laser includes a housing containing only a laser diode and an optical adjustment component (e.g., a collimating lens) for propagating a laser beam with a suitable beam profile. In these embodiments, lasers of interest in the subject laser assembly lack one or more components in conventional laser heads, such as beam shaping optical components (e.g., focusing lens, Powell lenses, etc.), light taping components and laser power meters. As described in greater detail below, one or more of these components may be separated from the laser assembly and mounted on the surface of a substrate (e.g., optical deck). In certain instances, the laser in the subject laser assembly consists of a laser diode and a collimating lens.

In embodiments, the laser assembly includes a thermoelectric cooler in contact with a bottom surface of the laser. The term “thermoelectric cooler” is used herein in its conventional sense to refer to a heat pump which transfers heat between the junction of two different surfaces (e.g., a “cool” surface and a “hot” surface) in response to the application of an electrical current. In certain embodiments, heat flux between the two different surfaces is generated by the Peltier effect and thermoelectric coolers of interest are Peltier heat pumps. In some embodiments, the two different surfaces (e.g. plates) of the thermoelectric cooler are formed from different materials (n-type semiconductors, p-type semiconductors), such as narrow band-gap semiconductors and heavy element materials having low thermal conductivity. For example, the surfaces of thermoelectric coolers of interest may be formed from semiconductors such as bismuth telluride, lead telluride, silicon germanium, bismuth-antimony alloys, and combinations thereof. In certain embodiments, thermoelectric coolers of interest include those described in U.S. Patent Publication No. 2004/0155251, U.S. Pat. Nos. 6,499,306; 4,581,898; 4,922,822; 5,409,547 and 2,984,077, the disclosures of which are incorporated herein by reference.

In embodiments of the laser assembly, the cooling surface of the thermoelectric cooler is in contact with a bottom surface of the laser. By “contact” is meant that the thermoelectric cooler is positioned adjacent to the bottom surface of the laser such that heat energy from the laser is transferred to the cooling surface of the thermoelectric cooler. In embodiments, the thermoelectric cooler may be positioned 10 mm or less from the bottom surface of the laser, such as 9 mm or less, such as 8 mm or less, such as 7 mm or less, such as 6 mm or less, such as 5 mm or less, such as 4 mm or less, such as 3 mm or less, such as 2 mm or less, such as 1 mm or less, such as 0.5 mm or less, such as 0.1 mm or less, such as 0.01 mm or less, such as 0.001 mm or less, such as 0.0001 mm or less and including 0.00001 mm or less from the bottom surface of the laser. For example, in the laser assembly, the thermoelectric cooler may be positioned from 0.00001 mm to 10 mm from the bottom surface of the laser, such as from 0.00005 mm to 9.5 mm, such as from 0.0001 mm to 9 mm, such as from 0.0005 mm to 8.5 mm, such as from 0.001 mm to 8 mm, such as from 0.005 mm to 7.5 mm, such as from 0.01 mm to 7 mm, such as from 0.05 mm to 6.5 mm, such as from 0.1 mm to 6 mm, such as from 0.5 mm to 5.5 mm and including from 1 mm to 5 mm. In certain embodiments, the thermoelectric cooler is in direct physical contact with the bottom surface of the laser (i.e., there is no space between the thermoelectric cooler and the bottom surface of the laser).

In some embodiments, the cooling surface of the thermoelectric cooler is 10 mm or less from the bottom surface of the laser, such as 9 mm or less, such as 8 mm or less, such as 7 mm or less, such as 6 mm or less, such as 5 mm or less, such as 4 mm or less, such as 3 mm or less, such as 2 mm or less, such as 1 mm or less, such as 0.5 mm or less, such as 0.1 mm or less, such as 0.01 mm or less, such as 0.001 mm or less, such as 0.0001 mm or less and including 0.00001 mm or less from the bottom surface of the laser. For example, in the laser assembly, the cooling surface of the thermoelectric cooler may be positioned from 0.00001 mm to 10 mm from the bottom surface of the laser, such as from 0.00005 mm to 9.5 mm, such as from 0.0001 mm to 9 mm, such as from 0.0005 mm to 8.5 mm, such as from 0.001 mm to 8 mm, such as from 0.005 mm to 7.5 mm, such as from 0.01 mm to 7 mm, such as from 0.05 mm to 6.5 mm, such as from 0.1 mm to 6 mm, such as from 0.5 mm to 5.5 mm and including from 1 mm to 5 mm. In certain embodiments, the cooling surface of the thermoelectric cooler is in direct physical contact with the bottom surface of the laser (i.e., there is no space between the cooling surface of the thermoelectric cooler and the bottom surface of the laser).

All or part of the bottom surface of the laser may be in contact with the thermoelectric cooler (e.g., the cooling surface of the thermoelectric cooler). In some embodiments, 10% or more of the bottom surface of the laser may be in contact with the thermoelectric cooler, such as 20% or more, such as 30% or more, such as 40% or more, such as 50% or more, such as 60% or more, such as 70% or more, such as 80% or more, such as 90% or more, such as 95% or more, such as 97% or more and including 99% or more. For example, 10% or more of the bottom surface of the laser may be in contact with the cooling surface of the thermoelectric cooler, such as 20% or more, such as 30% or more, such as 40% or more, such as 50% or more, such as 60% or more, such as 70% or more, such as 80% or more, such as 90% or more, such as 95% or more, such as 97% or more and including 99% or more. In certain embodiments, the entire (i.e., 100%) bottom surface of the laser is in contact with the thermoelectric cooler (e.g., cooling surface of the thermoelectric cooler).

In certain instances, the thermoelectric cooler surface in contact with the laser may extend beyond the bottom surface of the laser. Depending on the surface area of the bottom of the laser, the thermoelectric cooler surface in contact with the laser may have a length that extends 1 mm or more beyond the length of the bottom surface of the laser, such as 2 mm or more, such as 3 mm or more, such as 5 mm or more, such as 10 mm or more and including 25 mm or more beyond the length of the bottom surface of the laser. The width of the thermoelectric cooler surface in contact with the laser may also extend beyond the bottom surface of the laser, such as by 1 mm or more, such as by 2 mm or more, such as 3 mm or more, such as 5 mm or more, such as 10 mm or more and including 25 mm or more beyond the length of the bottom surface of the laser. In certain embodiments, the bottom surface of the laser has the same dimensions (i.e., length and width) as the surface of the thermoelectric cooler in contact with the laser.

In the subject laser assembly, a heat dissipation component is in contact with a bottom surface of the thermoelectric cooler. In embodiments, heat energy from the thermoelectric cooler is transferred to the heat dissipation component and dissipated into the ambient surroundings of the laser assembly (e.g., to the surroundings of the optical deck of a flow cytometer). In some embodiments, the heat dissipation component includes a heat transfer block and heat dissipation fins. As described in greater detail below, the heat dissipation component is configured to receive heat energy from the thermoelectric cooler and efficiently dissipate heat with little-to-no transfer of heat energy to the surface of an optical deck (e.g., an optical deck of a flow cytometer).

The heat transfer block may be any convenient shape, such as a cube, cone, cylinder, half sphere, star, triangular prism, rectangular prism (cuboid), hexagonal prism or other suitable polyhedron. For example, the cross-sectional area of the heat dissipation component that is contact with the bottom surface of the thermoelectric cooler may be in the shape of a circle, oval, half-circle, crescent-shaped, star-shaped, square, triangle, rhomboid, pentagon, hexagon, heptagon, octagon, rectangle or other suitable polygon. In certain instances, the heat transfer block is a rectangular shaped prism (cuboid) where a square cross-sectional area is positioned in contact with the bottom surface of the thermoelectric cooler. In other instances, the heat transfer block is a rectangular shaped prism (cuboid) where a rectangular cross-sectional area is positioned in contact with the bottom surface of the thermoelectric cooler.

Depending on the size of the thermoelectric cooler, the heat transfer block may have dimensions which vary, having a length that ranges from 5 mm to 100 mm, such as from 6 mm to 90 mm, such as from 7 mm to 80 mm, such as from 8 mm to 70 mm, such as from 9 mm to 60 mm and including from 10 mm to 50 mm; a width that ranges from 5 mm to 100 mm, such as from 6 mm to 90 mm, such as from 7 mm to 80 mm, such as from 8 mm to 70 mm, such as from 9 mm to 60 mm and including from 10 mm to 50 mm; and a height that ranges from 5 mm to 100 mm, such as from 6 mm to 90 mm, such as from 7 mm to 80 mm, such as from 8 mm to 70 mm, such as from 9 mm to 60 mm and including from 10 mm to 50 mm.

The cross-sectional area of the heat transfer block that contacts the bottom surface of thermoelectric cooler may vary, ranging from 10 mm² to 250 mm², such as from 20 mm² to 240 mm², such as from 30 mm² to 230 mm², such as from 40 mm² to 220 mm², such as from 50 mm² to 210 mm², such as from 60 mm² to 200 mm², such as from 75 mm² to 175 mm² and including from 100 mm² to 150 mm². In these embodiments, the length of the cross-sectional area of the heat transfer block that contacts the bottom surface of the thermoelectric cooler may range from 5 mm to 100 mm, such as from 6 mm to 90 mm, such as from 7 mm to 80 mm, such as from 8 mm to 70 mm, such as from 9 mm to 60 mm and including from 10 mm to 50 mm and the width of the cross-sectional area of the heat transfer block that contacts the bottom surface of the thermoelectric cooler may range from 5 mm to 100 mm, such as from 6 mm to 90 mm, such as from 7 mm to 80 mm, such as from 8 mm to 70 mm, such as from 9 mm to 60 mm and including from 10 mm to 50 mm.

The heat transfer block may be formed from any suitable heat transfer material, such as metals, metal composites, metal alloys, metal laminates, ceramics, metal ceramics, diamond-based heat transfer materials, semiconductors as well as thermally conductivity polymers (e.g., polyimides). In some embodiments, heat transfer blocks include one or more of copper, aluminum, brass, silver, gold, steel, lead, tungsten, molybdenum, copper-tungsten alloy, copper molybdenum alloy, aluminum nitride, boron nitride, aluminum silicon composites, silicon semiconductors, gallium arsenide, indium phosphide, gallium nitride, silicon carbide, aluminum oxide, beryllium oxide.

In some embodiments, the heat transfer block includes one or more cutouts, such as for example thermally insulating cutouts or cutouts configured to dissipate heat by thermal expansion. The cutout may be any convenient shape, where cutout shapes of interest include, but are not limited to: rectilinear cross sectional shapes, e.g., squares, rectangles, trapezoids, triangles, hexagons, etc., curvilinear cross-sectional shapes, e.g., circles, ovals, as well as irregular shapes, e.g., a parabolic bottom portion coupled to a planar top portion. The heat transfer block may include 1 or more cutouts, such as 2 or more, such as 3 or more, such as 4 or more, such as 5 or more, such as 6 or more, such as 7 or more, such as 8 or more, such as 9 or more and including 10 or more cutouts.

Depending on the size of the heat transfer block, the size of the cutout may vary, having a length that ranges from 0.5 mm to 25 mm, such as from 1 mm to 22.5 mm, such as from 1.5 mm to 20 mm, such as from 2 mm to 17.5 mm, such as from 2.5 mm to 15 mm and including from 3 mm to 10 mm; a width that ranges from 0.5 mm to 25 mm, such as from 1 mm to 22.5 mm, such as from 1.5 mm to 20 mm, such as from 2 mm to 17.5 mm, such as from 2.5 mm to 15 mm and including from 3 mm to 10 mm.

In some embodiments, the cutout is positioned at or near an edge where the heat transfer block is in contact with the bottom surface of the thermoelectric cooler. For example, the cutout may be positioned from 0.1 mm to 25 mm from an edge where the heat transfer block is in contact with the bottom surface of the thermoelectric cooler, such as 0.2 mm to 22.5 mm, such as from 0.3 mm to 20 mm, such as from 0.4 mm to 17.5 mm, such as from 0.5 mm to 15 mm, such as from 0.6 mm to 12.5 mm and including from 1 mm to 10 mm from an edge where the heat transfer block is in contact with the bottom surface of the thermoelectric cooler.

In some embodiments, the heat dissipation component includes one or more heat dissipation fins. Heat dissipation fins according to embodiments may be any convenient shape configured to dissipate heat from the heat transfer block and may be a cylinder, cube, cone, cylinder, half sphere, star, triangular prism, rectangular prism (cuboid), hexagonal prism or other suitable polyhedron. For example, the heat dissipation fin may have a cross-section in the shape of a circle, oval, half-circle, crescent-shaped, star-shaped, square, triangle, rhomboid, pentagon, hexagon, heptagon, octagon, rectangle or other polygon.

Depending on the size of the heat transfer block, the size of each heat dissipation fin may vary, each independently having a length that ranges from 0.5 mm to 50 mm, such as from 1 mm to 45 mm, such as from 2 mm to 40 mm, such as from 3 mm to 35 mm, such as from 4 mm to 30 mm and including from 5 mm to 25 mm; a width that ranges from 0.5 mm to 50 mm, such as from 1 mm to 45 mm, such as from 2 mm to 40 mm, such as from 3 mm to 35 mm, such as from 4 mm to 30 mm and including from 5 mm to 25 mm; and a height that ranges from 5 mm to 100 mm, such as from 6 mm to 90 mm, such as from 7 mm to 80 mm, such as from 8 mm to 70 mm, such as from 9 mm to 60 mm and including from 10 mm to 50 mm. In certain embodiments, heat dissipation fins of interest are cylindrical and each heat dissipation fin independently have a diameter that ranges from 0.5 mm to 50 mm, such as from 1 mm to 45 mm, such as from 2 mm to 40 mm, such as from 3 mm to 35 mm, such as from 4 mm to 30 mm and including from 5 mm to 25 mm and a length that ranges from 5 mm to 100 mm, such as from 6 mm to 90 mm, such as from 7 mm to 80 mm, such as from 8 mm to 70 mm, such as from 9 mm to 60 mm and including from 10 mm to 50 mm.

The heat dissipation component may, in certain embodiments, include a plurality of heat dissipation fins, such as 2 or more heat dissipation fins, such as 5 or more, such as 10 or more, such as 15 or more, such as 25 or more, such as 50 or more and including 100 or more heat dissipation fins. The heat dissipation fins may be mounted onto all or part of the heat transfer block, such as for example, where 5% or more of the surface area of the heat transfer block is covered by heat dissipation fins, such as 10% or more, such as 25% or more, such as 50% or more and including 75% or more. The heat dissipation fins may be positioned on the heat transfer block in any desired pattern, such as one or more lines, a polygonal pattern, a symmetric pattern or an asymmetric pattern. In certain embodiments, the heat dissipation fins are positioned on the heat transfer block in a grid pattern. The space between each heat dissipation fin may vary, ranging from 0.0001 mm to 25 mm, such as from 0.0005 mm to 22.5 mm, such as from 0.001 mm to 20 mm, such as from 0.005 mm to 17.5 mm, such as from 0.01 mm to 15 mm, such as from 0.05 mm to 12.5 mm and including from 0.1 mm to 10 mm.

The heat transfer fins may be formed from the same or a different material as the heat transfer block. For example, the heat transfer fins may be formed from metals, metal composites, metal alloys, metal laminates, ceramics, metal ceramics, diamond based heat transfer materials, semiconductors as well as thermally conductivity polymers (e.g., polyimides). In some embodiments, heat dissipation fins include one or more of copper, aluminum, brass, silver, gold, steel, lead, tungsten, molybdenum, copper-tungsten alloy, copper molybdenum alloy, aluminum nitride, boron nitride, aluminum silicon composites, silicon semiconductors, gallium arsenide, indium phosphide, gallium nitride, silicon carbide, aluminum oxide, beryllium oxide. In certain embodiments, the heat dissipation fins are formed from the same material as the heat transfer block. In other embodiments, the heat dissipation fins are formed from a different material as the heat transfer block.

Each heat dissipation fin may be affixed to the heat transfer block, such as with an adhesive or screw threaded into the heat transfer block or may be integrally formed with the heat transfer block. In certain embodiments, the heat dissipation fins and the heat transfer block are co-molded from the same heat transfer material (e.g., metal, metal alloy, metal composite, etc.).

In some embodiments, the heat dissipation component has planar symmetry or is axially symmetric. In these embodiments, the heat dissipation component is configured to dissipate heat energy symmetrically to the ambient surroundings, such as symmetrically outward from a vertical plane of the heat dissipation component or symmetrically along an axis of the heat dissipation component. In embodiments where the heat dissipation component has planar symmetry, the heat dissipation component may include two identical heat transfer blocks having the identical number and type of heat dissipation fins. For example, the heat dissipation component may include a first heat transfer block having a first set of heat dissipation fins and a second heat transfer block having a second set of heat dissipation fins, where the first heat transfer block and the second heat transfer block are positioned to have a vertical plane of symmetry therebetween. In these embodiments, the heat dissipation component is configured to dissipate heat symmetrically from the first heat transfer block and the second heat transfer block. In other embodiments, the heat dissipation component is axially symmetric. For example, the heat dissipation component may include a cylindrical heat transfer block with heat dissipation fins extending outward from the cylindrical heat transfer block.

As described herein, the heat dissipation component is positioned adjacent to the bottom surface of the thermoelectric cooler such that heat energy from the thermoelectric cooler (e.g., the “hot” surface of thermoelectric cooler) is transferred to the heat transfer block of the heat dissipation component. In embodiments, the heat transfer block may be positioned 10 mm or less from the bottom surface of the thermoelectric cooler, such as such as 9 mm or less, such as 8 mm or less, such as 7 mm or less, such as 6 mm or less, such as 5 mm or less, such as 4 mm or less, such as 3 mm or less, such as 2 mm or less, such as 1 mm or less, such as 0.5 mm or less, such as 0.1 mm or less, such as 0.01 mm or less, such as 0.001 mm or less, such as 0.0001 mm or less and including 0.00001 mm or less from the bottom surface of the thermoelectric cooler. For example, the heat transfer block may be positioned from 0.00001 mm to 10 mm from the bottom surface of the thermoelectric cooler, such as from 0.00005 mm to 9.5 mm, such as from 0.0001 mm to 9 mm, such as from 0.0005 mm to 8.5 mm, such as from 0.001 mm to 8 mm, such as from 0.005 mm to 7.5 mm, such as from 0.01 mm to 7 mm, such as from 0.05 mm to 6.5 mm, such as from 0.1 mm to 6 mm, such as from 0.5 mm to 5.5 mm and including from 1 mm to 5 mm. In certain embodiments, the heat transfer block is in direct physical contact with the bottom surface of the thermoelectric cooler (i.e., no space between the heat transfer block and the bottom surface of the thermoelectric cooler).

In some embodiments, the heated surface of the thermoelectric cooler (the surface that heat energy is transferred to in response to the applied electrical current) is positioned 10 mm or less from the heat transfer block, such as 9 mm or less, such as 8 mm or less, such as 7 mm or less, such as 6 mm or less, such as 5 mm or less, such as 4 mm or less, such as 3 mm or less, such as 2 mm or less, such as 1 mm or less, such as 0.5 mm or less, such as 0.1 mm or less, such as 0.01 mm or less, such as 0.001 mm or less, such as 0.0001 mm or less and including 0.00001 mm or less from the heat transfer block. For example, in the laser assembly, the heated surface of the thermoelectric cooler may be positioned from 0.00001 mm to 10 mm from the heat transfer block, such as from 0.00005 mm to 9.5 mm, such as from 0.0001 mm to 9 mm, such as from 0.0005 mm to 8.5 mm, such as from 0.001 mm to 8 mm, such as from 0.005 mm to 7.5 mm, such as from 0.01 mm to 7 mm, such as from 0.05 mm to 6.5 mm, such as from 0.1 mm to 6 mm, such as from 0.5 mm to 5.5 mm and including from 1 mm to 5 mm. In certain embodiments, the heated surface of the thermoelectric cooler is in direct physical contact with the heat transfer block (i.e., no space between the heated surface of the thermoelectric cooler and the heat transfer block).

All or part of the bottom surface of the thermoelectric cooler may be in contact with the heat transfer block. In some embodiments, 10% or more of the bottom surface of the thermoelectric cooler may be in contact with the heat transfer block, such as 20% or more, such as 30% or more, such as 40% or more, such as 50% or more, such as 60% or more, such as 70% or more, such as 80% or more, such as 90% or more, such as 95% or more, such as 97% or more and including 99% or more. For example, 10% or more of the bottom surface of the thermoelectric cooler may be in contact with the heat transfer block, such as 20% or more, such as 30% or more, such as 40% or more, such as 50% or more, such as 60% or more, such as 70% or more, such as 80% or more, such as 90% or more, such as 95% or more, such as 97% or more and including 99% or more. In certain embodiments, the entire (i.e., 100%) bottom surface of the thermoelectric cooler is in contact with the heat transfer block.

In certain instances, the surface of the heat transfer block in contact with the thermoelectric cooler may extend beyond the bottom surface of the thermoelectric cooler. Depending on the surface area of the bottom of the thermoelectric cooler, the surface of the heat transfer block in contact with the thermoelectric cooler may have a length that extends 1 mm or more beyond the length of the bottom surface of the thermoelectric cooler, such as 2 mm or more, such as 3 mm or more, such as 5 mm or more, such as 10 mm or more and including 25 mm or more beyond the length of the bottom surface of the thermoelectric cooler. The width of the surface of the heat transfer block in contact with the thermoelectric cooler may also extend beyond the bottom surface of the thermoelectric cooler, such as by 1 mm or more, such as by 2 mm or more, such as 3 mm or more, such as 5 mm or more, such as 10 mm or more and including 25 mm or more beyond the length of the bottom surface of the thermoelectric cooler. In certain embodiments, the bottom surface of the thermoelectric cooler has the same dimensions (i.e., length and width) as the surface of the heat transfer block in contact with the thermoelectric cooler.

In certain embodiments, the laser assembly includes one or more mounting pads in contact with a bottom surface of the heat dissipation component (e.g., on a bottom surface of the heat transfer block). In some instances, the mounting pads are electrically insulating. In other instances, the mounting pads are thermally insulating. In still other instances, the mounting pads are electrically insulating and thermally insulating. In these embodiments, the mounting pads may be formed from any suitable thermally insulating material, such as a non-thermally conductive polymer (e.g., polystyrene, polyurethane, polyisocyanurate, polyethylenimine), mineral wools, fiberglass, among other thermally insulating materials.

The mounting pad may be any convenient shape, where shapes of interest include, but are not limited to: rectilinear cross sectional shapes, e.g., squares, rectangles, trapezoids, triangles, hexagons, etc., curvilinear cross-sectional shapes, e.g., circles, ovals, as well as irregular shapes, e.g., a parabolic bottom portion coupled to a planar top portion. The bottom surface of the heat transfer block may include 1 or more mounting pads, such as 2 or more, such as 3 or more, such as 4 or more, such as 5 or more, such as 6 or more, such as 7 or more, such as 8 or more, such as 9 or more and including 10 or more mounting pads.

Depending on the size of the heat transfer block, the size of the mounting pad may vary, having a length that ranges from 0.5 mm to 25 mm, such as from 1 mm to 22.5 mm, such as from 1.5 mm to 20 mm, such as from 2 mm to 17.5 mm, such as from 2.5 mm to 15 mm and including from 3 mm to 10 mm and a width that ranges from 0.5 mm to 25 mm, such as from 1 mm to 22.5 mm, such as from 1.5 mm to 20 mm, such as from 2 mm to 17.5 mm, such as from 2.5 mm to 15 mm and including from 3 mm to 10 mm.

In some embodiments, the mounting pad is positioned at or near an edge of the bottom surface of the heat transfer block. For example, the mounting pad may be positioned from 0.1 mm to 25 mm from an edge of the bottom surface of the heat transfer block, such as 0.2 mm to 22.5 mm, such as from 0.3 mm to 20 mm, such as from 0.4 mm to 17.5 mm, such as from 0.5 mm to 15 mm, such as from 0.6 mm to 12.5 mm and including from 1 mm to 10 mm.

All or part of the bottom surface of the heat transfer block may be covered by the mounting pad, such as 10% or more of the bottom surface of the heat transfer block, such as 20% or more, such as 30% or more, such as 40% or more, such as 50% or more, such as 60% or more, such as 70% or more, such as 80% or more, such as 90% or more, such as 95% or more, such as 97% or more and including 99% or more. In certain embodiments, the mounting pad covers the entire bottom surface of the heat transfer block. Where the bottom surface of the heat transfer block includes more than one mounting pad, the space between each mounting pad may vary, ranging from 0.0001 mm to 25 mm, such as from 0.0005 mm to 22.5 mm, such as from 0.001 mm to 20 mm, such as from 0.005 mm to 17.5 mm, such as from 0.01 mm to 15 mm, such as from 0.05 mm to 12.5 mm and including from 0.1 mm to 10 mm.

The mounting pads may be positioned on the bottom surface of the heat transfer block in any desired pattern, such as one or more lines, a polygonal pattern, a symmetric pattern or an asymmetric pattern. In some embodiments, the mounting pads are positioned on the bottom surface of the heat transfer block in a grid pattern. In certain embodiments, the heat dissipation component is symmetrical and includes: 1) a first heat transfer block with a plurality of heat dissipation fins and a first mounting pad on the bottom surface of the first heat transfer block; and 2) a second heat transfer block with a plurality of heat dissipation fins and a second mounting pad on the bottom surface of the second heat transfer block, where the first mounting pad is identically positioned on the bottom surface of the first heat transfer block as the second mounting pad on the bottom surface of the second heat transfer block.

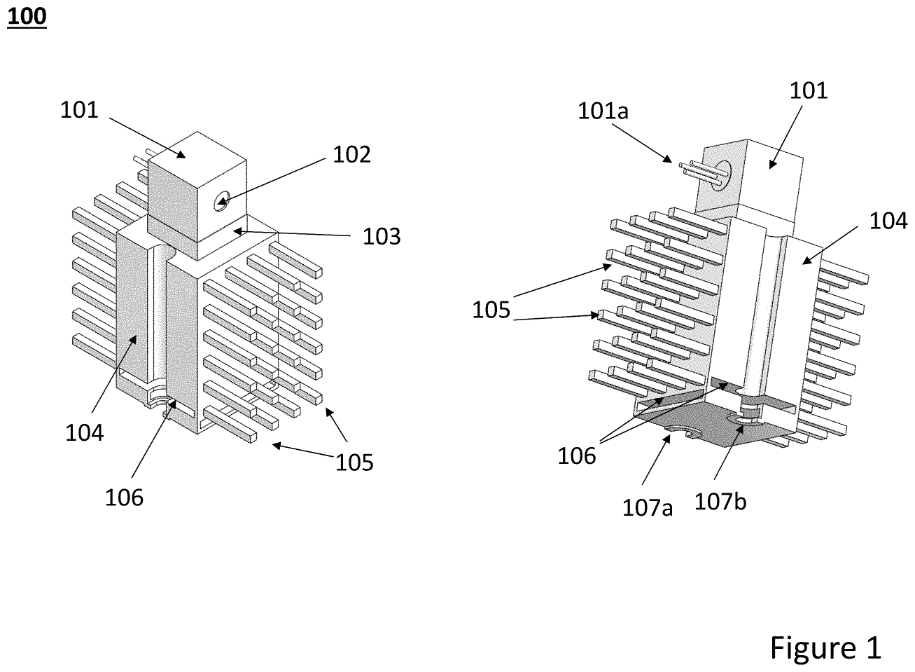

FIG. 1 depicts a laser assembly having a laser, a thermoelectric cooler and a heat dissipation component having a heat transfer block and heat dissipation fins according to certain embodiments. FIG. 1 depicts a top view of laser assembly 100. Laser assembly 100 includes a laser head 101 that includes a collimating lens 102 at the exit window of laser 101. In contact with a bottom surface of the laser is thermoelectric cooler 103. Heat energy from laser head 101 is transferred to the cooling surface of thermoelectric cooler 103. The bottom surface of thermoelectric cooler 103 is in contact with heat dissipation block 104. Heat transfer block 104 is symmetrical across a vertical plane and includes heat dissipation fins 105 on both sides. Heat transfer block 104 includes a cutout 106. FIG. 1 also depicts a bottom view of laser assembly 100. Laser head 101 includes a laser diode 101a. Mounting pads 107a and 107b for thermal isolation and opto-mechanical stability are positioned in contact with a bottom surface of the heat transfer block.

### Optical Deck Having a Mounted Laser Assembly

Aspects of the present disclosure also include an optical deck having one or more of the subject laser assemblies mounted onto a substrate. In certain embodiments, the substrate is a printed circuit board. In embodiments, little-to-no heat energy is transferred from the laser assembly (e.g., laser diode) to other components on the optical deck (e.g., beam shaping optics, as described below), such as where 25% or less of the heat energy from the laser assembly is transferred, such as 20% or less, such as 15% or less, such as 10% or less, such as 5% or less, such as 3% or less, such as 2% or less, such as 1% or less, such as 0.5% or less, such as 0.1% or less, such as 0.05% or less, such as 0.01% or less and including 0.001% or less. In certain embodiments, no heat energy is transferred from the laser assembly to other components on the optical deck.

All or part of the bottom surface of the heat transfer block may be in contact with the surface of optical deck substrate, such as 10% or more of the bottom surface of the heat transfer block, such as 20% or more, such as 30% or more, such as 40% or more, such as 50% or more, such as 60% or more, such as 70% or more, such as 80% or more, such as 90% or more, such as 95% or more, such as 97% or more and including 99% or more. In certain embodiments, the bottom surface of the heat transfer block does not contact the optical deck substrate surface and the heat transfer block is mounted onto the optical deck substrate with one or more mounting pads, as described above. In these embodiments, the only contact between the laser assembly and the optical deck substrate is through the mounting pads.

The laser assembly may be attached to a surface of the optical deck substrate by any convenient mounting protocol. In some embodiments, the laser assembly is non-releasably affixed to the optical deck substrate by molding, welding or affixing the laser assembly to the optical deck substrate with a permanent adhesive. In other embodiments, the laser assembly is releasably affixed to the optical deck substrate, such as with a hook and loop fastener, a latch, a notch, a groove, a pin, a tether, a hinge, Velcro, non-permanent adhesive, a threaded screw, or a combination thereof. Where the laser assembly includes one or more mounting pads, the laser assembly may be attached to the surface of the optical deck by affixing the mounting pad to the optical deck substrate. In certain embodiments, the laser assembly is not attached to the surface of the optical deck and is simply positioned on top of the optical deck substrate.

In embodiments, the optical deck may also include one or more optical adjustment components. The term “optical adjustment” is used herein in its conventional sense to refer to any device that is capable of changing the spatial width irradiation or some other characteristic of irradiation from the laser light, such as for example, irradiation direction, wavelength, beam width, beam intensity, focal point and pulse width. Optical adjustment protocols may be any convenient device which adjusts one or more characteristics of the laser, including but not limited to lenses, mirrors, filters, fiber optics, wavelength separators, pinholes, slits, collimating protocols and combinations thereof. In certain embodiments, the optical decks include one or more focusing lenses. The focusing lens, in one example may be a de-magnifying lens. In another example, the focusing lens is a magnifying lens. In other embodiments, the optical deck includes one or more mirrors. In still other embodiments, the optical deck includes a beam combiner, such as a dichroic mirror beam combiner.

As described above, the optical deck may also include one or more components that are found in conventional lasers, such as laser beam shapers, laser beam tuning components, choppers and pulse generators that have been separated from the laser in the subject laser assembly. In some embodiments, optical decks of interest include beam shaping optics. The beam shaping optics in these embodiments may include diffractive optics, refractive optics or an array of lenses, such as a cylindrical lens array. In some embodiments, the beam shaping optics include an aspheric cylindrical lens having cylindrical axes oriented at right angles, such as a laser line generator lens (e.g., a Powell lens). Examples of laser line generator lenses include, but are not limited to, those described in U.S. Pat. Nos. 4,826,299; 5,283,694; 7,400,457 and 7,329,860, the disclosures of which are herein incorporated by reference.

In certain embodiments, the optical deck includes a sensor for determining the intensity of the output beams of laser light from the laser assembly, including but not limited to, a scanning slit profiler, a charge coupled device (CCD, such as an intensified charge coupled device, ICCD), a positioning sensor, power sensor (e.g., a thermopile power sensor), optical power sensor, energy meter, digital laser photometer, a laser diode detector, among other types of photodetectors.

In some embodiments, the optical adjustment components are movable. In some instances, the optical adjustment component is movable in two dimensions, such as in an X-Y plane. In other instances, the optical adjustment component is movable in three dimensions. In certain embodiments, the optical adjustment component is configured to be moved to adjust the position of irradiation, such as on a flow stream.

Where the optical adjustment component is configured to move, the optical adjustment component may be configured to be moved continuously or in discrete intervals. In some embodiments, movement of the optical adjustment component is continuous. In other embodiments, the optical adjustment component is movable in discrete increments, such as for example in 0.01 micron or greater increments, such as 0.05 micron or greater, such as 0.1 micron or greater, such as 0.5 micron or greater, such as 1 micron or greater, such as 10 micron or greater, such as 100 microns or greater, such as 500 microns or greater, such as 1 mm or greater, such as 5 mm or greater, such as 10 mm or greater and including 25 mm or greater increments.

Any displacement protocol may be employed to move the optical adjustment component structures, such as coupled to a movable support stage or directly with a motor actuated translation stage, leadscrew translation assembly, geared translation device, such as those employing a stepper motor, servo motor, brushless electric motor, brushed DC motor, micro-step drive motor, high resolution stepper motor, among other types of motors.

Flow Cytometer Systems Having a Laser Assembly for Irradiating a Sample in a Flow Stream As summarized above, aspects of the present disclosure also include flow cytometer systems for characterizing particles in a flow stream. Flow cytometer systems according to embodiments include a flow cell configured to propagate a sample in a flow stream, a sensor to detect light signals from the flow stream and a laser assembly that includes a laser, a thermoelectric cooler in contact with a bottom surface of the laser and a heat dissipation component in contact with a bottom surface of the thermoelectric cooler, e.g., as described above. As described above, the laser assembly includes one or more lasers for irradiating a sample in the flow stream. The subject flow cytometer systems may include a laser assembly having one or more lasers, such as two or more lasers, such as 3 or more lasers, such as 4 or more lasers, such as 5 or more lasers, such as 6 or more lasers and including 10 or more lasers. Lasers of interest may include pulsed lasers or continuous wave lasers. The type and number of lasers may vary and may be a diode laser, a gas laser, such as a helium-neon laser, argon laser, krypton laser, xenon laser, nitrogen laser, CO₂ laser, CO laser, argon-fluorine (ArF) excimer laser, krypton-fluorine (KrF) excimer laser, xenon chlorine (XeCl) excimer laser or xenon-fluorine (XeF) excimer laser or a combination thereof. In others instances, laser assemblies of interest include a dye laser, such as a stilbene, coumarin or rhodamine laser. In yet other instances, the laser assembly includes a metal-vapor laser, such as a helium-cadmium (HeCd) laser, helium-mercury (HeHg) laser, helium-selenium (HeSe) laser, helium-silver (HeAg) laser, strontium laser, neon-copper (NeCu) laser, copper laser or gold laser and combinations thereof. In still other instances, the laser assembly includes a ruby laser, an Nd:YAG laser, NdCrYAG laser, Er:YAG laser, Nd:YLF laser, Nd:YVO₄ laser, Nd:YCa₄O(BO₃)₃ laser, Nd:YCOB laser, titanium sapphire laser, thulium YAG laser, ytterbium YAG laser, ytterbium₂O₃ laser or cerium doped lasers and combinations thereof. In still other instances, the laser assembly includes a semiconductor diode laser, optically pumped semiconductor laser (OPSL), or a frequency doubled- or frequency tripled implementation of any of the above mentioned lasers.

The laser may be configured to irradiate continuously or in discrete intervals. In some instances, systems include a laser that is configured to irradiate continuously, such as with a continuous wave laser that continuously irradiates the flow stream at the interrogation point in a flow cytometer. In other instances, systems of interest include a laser that is configured to irradiate the flow stream at discrete intervals, such as every 0.001 milliseconds, every 0.01 milliseconds, every 0.1 milliseconds, every 1 millisecond, every 10 milliseconds, every 100 milliseconds and including every 1000 milliseconds, or some other interval. Where the laser is configured to irradiate at discrete intervals, systems may include one or more additional components to provide for intermittent irradiation with the laser. For example, the subject systems in these embodiments may include one or more laser beam choppers, manually or computer controlled beam stops for blocking and exposing the flow stream to the laser.

In some embodiments, systems include a flow cell configured to propagate a sample in a flow stream. Any convenient flow cell which propagates a fluidic sample to a sample interrogation region may be employed, where in some embodiments, the flow cell includes is a cylindrical flow cell, a frustoconical flow cell or a flow cell that includes a proximal cylindrical portion defining a longitudinal axis and a distal frustoconical portion which terminates in a flat surface having the orifice that is transverse to the longitudinal axis.

In some embodiments, the sample flow stream emanates from an orifice at the distal end of the flow cell. Depending on the desired characteristics of the flow stream, the flow cell orifice may be any suitable shape where cross-sectional shapes of interest include, but are not limited to: rectilinear cross sectional shapes, e.g., squares, rectangles, trapezoids, triangles, hexagons, etc., curvilinear cross-sectional shapes, e.g., circles, ovals, as well as irregular shapes, e.g., a parabolic bottom portion coupled to a planar top portion. In certain embodiments, flow cell of interest has a circular orifice. The size of the nozzle orifice may vary, in some embodiments ranging from 1 μm to 20000 μm, such as from 2 μm to 17500 μm, such as from 5 μm to 15000 μm, such as from 10 μm to 12500 μm, such as from 15 μm to 10000 μm, such as from 25 μm to 7500 μm, such as from 50 μm to 5000 μm, such as from 75 μm to 1000 μm, such as from 100 μm to 750 μm and including from 150 μm to 500 μm. In certain embodiments, the nozzle orifice is 100 μm.

In some embodiments, the flow cell includes a sample injection port configured to provide a sample to the flow cell. In embodiments, the sample injection system is configured to provide suitable flow of sample to the flow cell inner chamber. Depending on the desired characteristics of the flow stream, the rate of sample conveyed to the flow cell chamber by the sample injection port may be 1 μL/min or more, such as 2 μL/min or more, such as 3 μL/min or more, such as 5 μL/min or more, such as 10 μL/min or more, such as 15 μL/min or more, such as 25 μL/min or more, such as 50 μL/min or more and including 100 μL/min or more, where in some instances the rate of sample conveyed to the flow cell chamber by the sample injection port is 1 μL/sec or more, such as 2 μL/sec or more, such as 3 μL/sec or more, such as 5 μL/sec or more, such as 10 μL/sec or more, such as 15 μL/sec or more, such as 25 μL/sec or more, such as 50 μL/sec or more and including 100 μL/sec or more.

The sample injection port may be an orifice positioned in a wall of the inner chamber or may be a conduit positioned at the proximal end of the inner chamber. Where the sample injection port is an orifice positioned in a wall of the inner chamber, the sample injection port orifice may be any suitable shape where cross-sectional shapes of interest include, but are not limited to: rectilinear cross sectional shapes, e.g., squares, rectangles, trapezoids, triangles, hexagons, etc., curvilinear cross-sectional shapes, e.g., circles, ovals, etc., as well as irregular shapes, e.g., a parabolic bottom portion coupled to a planar top portion. In certain embodiments, the sample injection port has a circular orifice. The size of the sample injection port orifice may vary depending on shape, in certain instances, having an opening ranging from 0.1 mm to 5.0 mm, e.g., 0.2 to 3.0 mm, e.g., 0.5 mm to 2.5 mm, such as from 0.75 mm to 2.25 mm, such as from 1 mm to 2 mm and including from 1.25 mm to 1.75 mm, for example 1.5 mm.

In certain instances, the sample injection port is a conduit positioned at a proximal end of the flow cell inner chamber. For example, the sample injection port may be a conduit positioned to have the orifice of the sample injection port in line with the flow cell orifice. Where the sample injection port is a conduit positioned in line with the flow cell orifice, the cross-sectional shape of the sample injection tube may be any suitable shape where cross-sectional shapes of interest include, but are not limited to: rectilinear cross sectional shapes, e.g., squares, rectangles, trapezoids, triangles, hexagons, etc., curvilinear cross-sectional shapes, e.g., circles, ovals, as well as irregular shapes, e.g., a parabolic bottom portion coupled to a planar top portion. The orifice of the conduit may vary depending on shape, in certain instances, having an opening ranging from 0.1 mm to 5.0 mm, e.g., 0.2 to 3.0 mm, e.g., 0.5 mm to 2.5 mm, such as from 0.75 mm to 2.25 mm, such as from 1 mm to 2 mm and including from 1.25 mm to 1.75 mm, for example 1.5 mm. The shape of the tip of the sample injection port may be the same or different from the cross-section shape of the sample injection tube. For example, the orifice of the sample injection port may include a beveled tip having a bevel angle ranging from 1° to 10°, such as from 2° to 9°, such as from 3° to 8°, such as from 4° to 7° and including a bevel angle of 5°.

In some embodiments, the flow cell also includes a sheath fluid injection port configured to provide a sheath fluid to the flow cell. In embodiments, the sheath fluid injection system is configured to provide a flow of sheath fluid to the flow cell inner chamber, for example in conjunction with the sample to produce a laminated flow stream of sheath fluid surrounding the sample flow stream. Depending on the desired characteristics of the flow stream, the rate of sheath fluid conveyed to the flow cell chamber by the may be 25 μL/sec or more, such as 50 μL/sec or more, such as 75 μL/sec or more, such as 100 μL/sec or more, such as 250 μL/sec or more, such as 500 μL/sec or more, such as 750 μL/sec or more, such as 1000 μL/sec or more and including 2500 μL/sec or more.

In some embodiments, the sheath fluid injection port is an orifice positioned in a wall of the inner chamber. The sheath fluid injection port orifice may be any suitable shape where cross-sectional shapes of interest include, but are not limited to: rectilinear cross sectional shapes, e.g., squares, rectangles, trapezoids, triangles, hexagons, etc., curvilinear cross-sectional shapes, e.g., circles, ovals, as well as irregular shapes, e.g., a parabolic bottom portion coupled to a planar top portion. The size of the sample injection port orifice may vary depending on shape, in certain instances, having an opening ranging from 0.1 mm to 5.0 mm, e.g., 0.2 to 3.0 mm, e.g., 0.5 mm to 2.5 mm, such as from 0.75 mm to 2.25 mm, such as from 1 mm to 2 mm and including from 1.25 mm to 1.75 mm, for example 1.5 mm.

In some embodiments, flow cytometer systems further include a pump in fluid communication with the flow cell to propagate the flow stream through the flow cell. Any convenient fluid pump protocol may be employed to control the flow of the flow stream through the flow cell. In certain instances, systems include a peristaltic pump, such as a peristaltic pump having a pulse damper. The pump in the subject systems is configured to convey fluid through the flow cell at a rate suitable for multi-photon counting of light from the sample in the flow stream. In some instances, the rate of sample flow in the flow cell is 1 nL/min or more, such as 2 nL/min or more, such as 3 nL/min or more, such as 5 nL/min or more, such as 10 nL/min or more, such as 25 nL/min or more, such as 50 nL/min or more, such as 75 nL/min or more, such as 100 nL/min or more, such as 250 nL/min or more, such as 500 nL/min or more, such as 750 nL/min or more and including 1000 nL/min or more. For example, the system may include a pump that is configured to flow sample through the flow cell at a rate that ranges from 1 nL/min to 500 nL/min, such as from 1 nL/min to 250 nL/min, such as from 1 nL/min to 100 nL/min, such as from 2 nL/min to 90 nL/min, such as from 3 nL/min to 80 nL/min, such as from 4 nL/min to 70 nL/min, such as from 5 nL/min to 60 nL/min and including from 10 nL/min to 50 nL/min. In certain embodiments, the flow rate of the flow stream is from 5 nL/min to 6 nL/min.

Flow cytometer systems of interest also include one or more photodetectors for detecting light signals from samples irradiated in the flow stream. Photodetectors in the subject systems may be any convenient light detecting protocol, including but not limited to photosensors or photodetectors, such as active-pixel sensors (APSs), quadrant photodiodes, image sensors, charge-coupled devices (CCDs), intensified charge-coupled devices (ICCDs), light emitting diodes, photon counters, bolometers, pyroelectric detectors, photoresistors, photovoltaic cells, photodiodes, photomultiplier tubes, phototransistors, quantum dot photoconductors or photodiodes and combinations thereof, among other photodetectors. In certain embodiments, the flow cytometers of interest include a photodiode array having more than one photodiode, such as two or more photodiodes, such as three or more, such as five or more and including 10 or more photodiodes, where each photodiode may have an active detecting surface area of each region that ranges from 0.01 cm² to 10 cm², such as from 0.05 cm² to 9 cm², such as from, such as from 0.1 cm² to 8 cm², such as from 0.5 cm² to 7 cm² and including from 1 cm² to 5 cm².

The photodetector may be positioned at any suitable distance from the flow stream so long as a usable light signal is detectable. For example, detectors in the subject systems may be positioned 1 mm or more from the flow stream, such as 5 mm or more, such as 10 mm or more, such as 15 mm or more, such as 25 mm or more, such as 50 mm or more, such as 100 mm or more, such as 150 mm or more, such as 250 mm or more and including 500 mm or more from the flow stream. The detectors may also be positioned at any angle from the flow stream. For example, the detectors may be angled with respect to the vertical axis of the flow stream at from 10° to 90°, such as from 15° to 85°, such as from 20° to 80°, such as from 25° to 75° and including from 30° to 60°. In some instances, the one or more detectors are positioned at 30° to 60° with respect to the vertical axis of the flow stream.

In embodiments, flow cytometer systems are configured to detect forward scattered light, side scattered light, emitted light, transmitted light or a combination thereof. In certain embodiments, the light signals from the irradiated flow stream may be detected by one or more detectors configured as forward scatter detectors. In these embodiments, the forward scatter detectors are positioned on the opposite side of the flow stream from the light source and are positioned to collect and detect forward propagated (e.g., scattered) light. In other embodiments, the subject systems are configured to detect light signals from light propagated upstream by total internal reflectance. In certain embodiments, the subject systems are configured with flow cell nozzles as described in published PCT Application WO 2014/176366, the disclosure of which is herein incorporated by reference.

Aspects of the invention further include flow cytometric systems having multiple lasers and a beam shaping component configured to generate output beams of light having a predetermined beam profile intensity along a horizontal axis as described above. Suitable flow cytometry systems and methods for analyzing samples include, but are not limited to those described in Ormerod (ed.), Flow Cytometry: A Practical Approach, Oxford Univ. Press (1997); Jaroszeski et al. (eds.), Flow Cytometry Protocols, Methods in Molecular Biology No. 91, Humana Press (1997); Practical Flow Cytometry, 3rd ed., Wiley-Liss (1995); Virgo, et al. (2012) Ann Clin Biochem. January; 49(pt 1):17-28; Linden, et. al., Semin Throm Hemost. 2004 October; 30(5):502-11; Alison, et al. J Pathol, 2010 December; 222(4):335-344; and Herbig, et al. (2007) Crit Rev Ther Drug Carrier Syst. 24(3):203-255; the disclosures of which are incorporated herein by reference. In certain instances, flow cytometry systems of interest include BD Biosciences FACSCanto™ flow cytometer, BD Biosciences FACSVantage™, BD Biosciences FACSort™, BD Biosciences FACSCount™, BD Biosciences FACScan™, and BD Biosciences FACSCalibur™ systems, a BD Biosciences Influx™ cell sorter, BD Biosciences Jazz™ cell sorter and BD Biosciences Aria™ cell sorter or the like.

In some embodiments, the subject systems are flow cytometric systems, such those described in U.S. Pat. Nos. 3,960,449; 4,347,935; 4,667,830; 4,704,891; 4,770,992; 5,030,002; 5,040,890; 5,047,321; 5,245,318; 5,317,162; 5,464,581; 5,483,469; 5,602,039; 5,620,842; 5,627,040; 5,643,796; 5,700,692; 6,372,506; 6,809,804; 6,813,017; 6,821,740; 7,129,505; 7,201,875; 7,544,326; 8,140,300; 8,233,146; 8,753,573; 8,975,595; 9,092,034; 9,095,494 and 9,097,640; the disclosure of which are herein incorporated by reference in their entirety.

In certain embodiments, the subject systems are flow cytometric systems having an excitation module that uses radio-frequency multiplexed excitation to generate a plurality of frequency shifted beams of light. In these embodiments, the laser light generator may include a plurality of lasers and one or more acousto-optic components (e.g., an acoustooptic deflector, an acoustooptic frequency shifter) to generate a plurality of frequency shifted comb beams. One or more of the frequency shifted comb beams and local oscillator beams may be configured to be received by a beam shaping component as described here to produce one or more beams of frequency shifted light having a substantially constant intensity profile. In certain instances, the subject systems are flow cytometric systems having a laser excitation module as described in U.S. Pat. Nos. 9,423,353 and 9,784,661 and U.S. Patent Publication Nos. 2017/0133857 and 2017/0350803, the disclosures of which are herein incorporated by reference.

### Methods for Irradiating a Sample in a Flow Stream

Aspects of the disclosure also include methods for irradiating a sample in a flow stream with a laser assembly having a laser, a thermoelectric cooler in contact with a bottom surface of the laser and a heat dissipation component in contact with a bottom surface of the thermoelectric cooler, as described above. In practicing methods according to certain embodiments, a flow stream is irradiated by the beams of laser light from the laser of the laser assembly. Light from the flow stream may be forward scattered light, side scattered light, transmitted light, emitted light (e.g., fluorescence or phosphorescence) or a combination thereof. In some embodiments, methods include collecting and detecting forward scattered light from the flow stream. In other embodiments, methods include collecting and detecting side scattered light from the flow stream. In yet other embodiments, methods include collecting and detecting light transmitted through the flow stream. In still other embodiments, methods include collecting and detecting emitted light (e.g., fluorescence or phosphorescence) from the flow stream.

The flow stream may be irradiated at any suitable vertical position along the flow stream so long as light signals from the flow stream are sufficiently detected. In certain embodiments, the flow stream is a flow cytometer flow stream and is configured to irradiate the flow stream at a position immediately adjacent to the flow cell nozzle orifice. In other embodiments, the flow stream is irradiated at a position downstream from the flow cell nozzle orifice, such as at a position 0.001 mm from the flow cell nozzle orifice, such as 0.005 mm or more, such as 0.01 mm or more, such as 0.05 mm or more, such as 0.1 mm or more, such as 0.5 mm or more, such as 1 mm or more, such as 2 mm or more, such as 5 mm or more and including 10 mm or more downstream from the flow cell nozzle orifice. The flow stream may be irradiated at one or more vertical positions, such as at 2 or more, such as at 3 or more, such as at 4 or more, such as at 5 or more and including irradiating the flow stream at 10 or more vertical positions.

Lasers of interest may include pulsed lasers or continuous wave lasers. For example, the laser may be a helium-neon laser, argon laser, krypton laser, xenon laser, nitrogen laser, CO₂ laser, CO laser, argon-fluorine (ArF) excimer laser, krypton-fluorine (KrF) excimer laser, xenon chlorine (XeCl) excimer laser or xenon-fluorine (XeF) excimer laser or a combination thereof. In others instances, the methods include aligning a dye laser with a flow stream, such as a stilbene, coumarin or rhodamine laser. In yet other instances, methods include aligning metal-vapor laser with a flow stream, such as a helium-cadmium (HeCd) laser, helium-mercury (HeHg) laser, helium-selenium (HeSe) laser, helium-silver (HeAg) laser, strontium laser, neon-copper (NeCu) laser, copper laser or gold laser and combinations thereof. In still other instances, methods include aligning a solid-state laser with a flow stream, such as a ruby laser, an Nd:YAG laser, NdCrYAG laser, Er:YAG laser, Nd:YLF laser, Nd:YVO₄ laser, Nd:YCa₄O(BO₃)₃ laser, Nd:YCOB laser, titanium sapphire laser, thulium YAG laser, ytterbium YAG laser, ytterbium₂O₃ laser or cerium doped lasers and combinations thereof.

The flow stream may be irradiated continuously or in discrete intervals. In some instances, methods include irradiating the flow stream continuously. In other instances, the flow stream is irradiated in discrete intervals, such as irradiating every 0.001 millisecond, every 0.01 millisecond, every 0.1 millisecond, every 1 millisecond, every 10 milliseconds, every 100 milliseconds and including every 1000 milliseconds, or some other interval.

Light signals from the flow stream may be detected by any convenient positional sensing detecting protocol, including but not limited to photosensors or photodetectors, such as active-pixel sensors (APSs), quadrant photodiodes, image sensors, charge-coupled devices (CCDs), intensified charge-coupled devices (ICCDs), light emitting diodes, photon counters, bolometers, pyroelectric detectors, photoresistors, photovoltaic cells, photodiodes, photomultiplier tubes, phototransistors, quantum dot photoconductors or photodiodes and combinations thereof, among other photodetectors. In certain embodiments, the light signals are detected with a quadrant photodiode. Where the light signals are detected with a quadrant photodiode, the active detecting surface area of each region of the quadrant photodiode may vary, such as from 0.01 cm² to 10 cm², such as from 0.05 cm² to 9 cm², such as from, such as from 0.1 cm² to 8 cm², such as from 0.5 cm² to 7 cm² and including from 1 cm² to 5 cm². In some instances, the photodetector is a photodiode array having more than one photodiode, such as two or more photodiodes, such as three or more, such as five or more and including 10 or more photodiodes.

In certain embodiments, the detector is positioned apart in space from the flow stream and light from the flow stream is propagated to the detector through an optical relay system, such as with fiber optics or a free space light relay system. For example, the optical relay system may be a fiber optics light relay bundle and light is conveyed through the fiber optics light relay bundle to the detector. Any fiber optics light relay system may be employed to propagate light to the detector. In certain embodiments, suitable fiber optics light relay systems for propagating light to the detector include, but are not limited to, fiber optics light relay systems such as those described in U.S. Pat. No. 6,809,804, the disclosure of which is herein incorporated by reference. In other embodiments, the optical relay system is a free-space light relay system. The phrase “free-space light relay” is used herein in its conventional sense to refer to light propagation that employs a configuration of one or more optical components to direct light to the detector through free-space. In certain embodiments, the free-space light relay system includes a housing having a proximal end and a distal end, the proximal end being coupled to the detector. The free-space relay system may include any combination of different beam shaping components, such as one or more of lenses, mirrors, slits, pinholes, wavelength separators, or a combination thereof. For example, in some embodiments, free-space light relay systems of interest include one or more focusing lens. In other embodiments, the subject free-space light relay systems include one or more mirrors. In yet other embodiments, the free-space light relay system includes a collimating lens. In certain embodiments, suitable free-space light relay systems for propagating light to the detector, but are not limited to, light relay systems such as those described in U.S. Pat. Nos. 7,643,142; 7,728,974 and 8,223,445, the disclosures of which is herein incorporated by reference.

Methods also include detecting light from the sample in the flow stream. The light detected may be side scattered light, forward scattered light, emitted light or combination thereof. Suitable light detecting protocols, include but are not limited to optical sensors or photodetectors, such as active-pixel sensors (APSs), avalanche photodiode, image sensors, charge-coupled devices (CCDs), intensified charge-coupled devices (ICCDs), light emitting diodes, photon counters, bolometers, pyroelectric detectors, photoresistors, photovoltaic cells, photodiodes, photomultiplier tubes, phototransistors, quantum dot photoconductors or photodiodes and combinations thereof, among other photodetectors. In certain embodiments, light from the irradiated flow stream at the sample interrogation region of the particle sorting module is measured with a charge-coupled device (CCD), semiconductor charge-coupled devices (CCD), active pixel sensors (APS), complementary metal-oxide semiconductor (CMOS) image sensors or N-type metal-oxide semiconductor (NMOS) image sensors. In certain embodiments, light is measured with a charge-coupled device (CCD).

Light signals from the flow stream may be measured at one or more wavelengths, such as at 2 or more wavelengths, such as at 5 or more different wavelengths, such as at 10 or more different wavelengths, such as at 25 or more different wavelengths, such as at 50 or more different wavelengths, such as at 100 or more different wavelengths, such as at 200 or more different wavelengths, such as at 300 or more different wavelengths and including measuring light from the flow stream at 400 or more different wavelengths. In some embodiments, methods include measuring light over a range of wavelengths (e.g., 200 nm-1000 nm). For example, methods may include collecting spectra of light over one or more of the wavelength ranges of 200 nm-1000 nm. In yet other embodiments, methods include measuring light from the flow stream at one or more specific wavelengths. For example, the light may be measured at one or more of 450 nm, 518 nm, 519 nm, 561 nm, 578 nm, 605 nm, 607 nm, 625 nm, 650 nm, 660 nm, 667 nm, 670 nm, 668 nm, 695 nm, 710 nm, 723 nm, 780 nm, 785 nm, 647 nm, 617 nm and any combinations thereof. In certain embodiments, methods including measuring wavelengths of light which correspond to the fluorescence peak wavelength of certain fluorophores.

Light from the flow stream may be measured continuously or in discrete intervals. In some instances, methods include taking measurements of the light continuously. In other instances, the light is measured in discrete intervals, such as measuring light every 0.001 millisecond, every 0.01 millisecond, every 0.1 millisecond, every 1 millisecond, every 10 milliseconds, every 100 milliseconds and including every 1000 milliseconds, or some other interval.

Measurements of the light may be taken one or more times during the subject methods, such as 2 or more times, such as 3 or more times, such as 5 or more times and including 10 or more times. In certain embodiments, the light propagation is measured 2 or more times, with the data in certain instances being averaged.

The flow rate of the flow stream according to embodiments may vary, e.g., depending on the intensity of the laser light and may be 1 nL/min or more, such as 2 nL/min or more, such as 3 nL/min or more, such as 5 nL/min or more, such as 10 nL/min or more, such as 25 nL/min or more, such as 50 nL/min or more, such as 75 nL/min or more, such as 100 nL/min or more, such as 250 nL/min or more, such as 500 nL/min or more, such as 750 nL/min or more and including 1000 nL/min or more. In certain embodiments, the flow rate of the flow stream in the subject methods ranges from 1 nL/min to 500 nL/min, such as from 1 nL/min to 250 nL/min, such as from 1 nL/min to 100 nL/min, such as from 2 nL/min to 90 nL/min, such as from 3 nL/min to 80 nL/min, such as from 4 nL/min to 70 nL/min, such as from 5 nL/min to 60 nL/min and including from 10 nL/min to 50 nL/min. In certain embodiments, the flow rate of the flow stream is from 5 nL/min to 6 nL/min.

In embodiments, methods may include irradiating different positions along the longitudinal axis of the flow stream. For example, methods may include irradiating positions along the longitudinal axis of the flow stream which differ by 0.0001 mm or more, such as by 0.0005 mm or more, such as by 0.001 mm or more, such as by 0.005 mm or more, such as by 0.01 mm or more, such as by 0.05 mm or more, such as by 0.1 mm or more, such as by 0.5 mm or more, such as by 1 mm or more, such as by 2 mm or more, such as by 3 mm or more, such as by 4 mm or more, such as by 5 mm or more, such as by 10 mm or more, such as by 15 mm or more and including by 25 mm or more. In certain embodiments, light may be propagated onto the flow stream at positions along the longitudinal axis that differ by 50 mm or less, such as by 25 mm or less, such as by 15 mm or less, such as by 10 mm or less, such as by 5 mm or less, such as by 4 mm or less, such as by 3 mm or less, such as by 2 mm or less, such as by 1 mm or less, such as by 0.5 mm or less, such as by 0.1 mm or less and including by 0.001 mm or less.

In some embodiments, the sample is a biological sample. The term “biological sample” is used in its conventional sense to refer to a whole organism, plant, fungi or a subset of animal tissues, cells or component parts which may in certain instances be found in blood, mucus, lymphatic fluid, synovial fluid, cerebrospinal fluid, saliva, bronchoalveolar lavage, amniotic fluid, amniotic cord blood, urine, vaginal fluid and semen. As such, a “biological sample” refers to both the native organism or a subset of its tissues as well as to a homogenate, lysate or extract prepared from the organism or a subset of its tissues, including but not limited to, for example, plasma, serum, spinal fluid, lymph fluid, sections of the skin, respiratory, gastrointestinal, cardiovascular, and genitourinary tracts, tears, saliva, milk, blood cells, tumors, organs. Biological samples may be any type of organismic tissue, including both healthy and diseased tissue (e.g., cancerous, malignant, necrotic, etc.). In certain embodiments, the biological sample is a liquid sample, such as blood or derivative thereof, e.g., plasma, or other biological liquid sample, e.g., tears, urine, semen, etc., where in some instances the sample is a blood sample, including whole blood, such as blood obtained from venipuncture or fingerstick (where the blood may or may not be combined with any reagents prior to assay, such as preservatives, anticoagulants, etc.).

In certain embodiments the source of the sample is a “mammal” or “mammalian”, where these terms are used broadly to describe organisms which are within the class mammalia, including the orders carnivore (e.g., dogs and cats), rodentia (e.g., mice, guinea pigs, and rats), and primates (e.g., humans, chimpanzees, and monkeys). In some instances, the subjects are humans. The methods may be applied to samples obtained from human subjects of both genders and at any stage of development (i.e., neonates, infant, juvenile, adolescent, adult), where in certain embodiments the human subject is a juvenile, adolescent or adult. While the present invention may be applied to samples from a human subject, it is to be understood that the methods may also be carried-out on samples from other animal subjects (that is, in “non-human subjects”) such as, but not limited to, birds, mice, rats, dogs, cats, livestock and horses.

In certain embodiments, the biological sample contains cells. Cells that may be present in the sample include eukaryotic cells (e.g., mammalian cells) and/or prokaryotic cells (e.g., bacterial cells or archaeal cells). Samples may be obtained from an in vitro source (e.g., a suspension of cells from laboratory cells grown in culture) or from an in vivo source (e.g., a mammalian subject, a human subject, etc.). In some embodiments, the cellular sample is obtained from an in vitro source. In vitro sources include, but are not limited to, prokaryotic (e.g., bacterial, archaeal) cell cultures, environmental samples that contain prokaryotic and/or eukaryotic (e.g., mammalian, protest, fungal, etc.) cells, eukaryotic cell cultures (e.g., cultures of established cell lines, cultures of known or purchased cell lines, cultures of immortalized cell lines, cultures of primary cells, cultures of laboratory yeast, etc.), tissue cultures, and the like.

Where the biological sample includes cells, methods of the present disclosure may include characterizing components of the cells, such as cell fragments, fragmented cell membranes, organelles, dead or lysed cells. In some embodiments, methods include characterizing the extracellular vesicles of the cells. Characterizing the extracellular vesicles of the cells may include identifying the type of extracellular vesicles in the cells or determining the size of the extracellular vesicles in the cells.

In some embodiments, light (e.g., forward scattered light, side scattered light, emitted light, etc.) is detected directly from the sample in the flow stream. In other embodiments, light from the sample in the flow stream is propagated to a detector with one or more beam optical adjustment components. For example, the beam path, direction, focus or collimation of the light from the sample in the flow stream may be changed with the optical adjustment component. In some instances, the dimensions of the light collected from the sample in the flow stream is adjusted, such as increasing the dimensions by 5% or more, such as by 10% or more, such as by 25% or more, such as by 50% or more and including increasing the dimensions by 75% or more or focusing the light so as to reduce the light dimensions, such as by 5% or greater, such as by 10% or greater, such as by 25% or greater, such as by 50% or greater and including reducing the dimensions by 75% or greater. In other instances, optical adjustment includes collimating the light. The term “collimate” is used in its conventional sense to refer to the optically adjusting the collinearity of light propagation or reducing divergence by the light of from a common axis of propagation. In some instances, collimating includes narrowing the spatial cross section of a light beam. In certain embodiments, the optical adjustment component is a wavelength separator. The term “wavelength separator” is used herein in its conventional sense to refer to an optical protocol for separating polychromatic light into its component wavelengths. Wavelength separation, according to certain embodiments, may include selectively passing or blocking specific wavelengths or wavelength ranges of the polychromatic light. Wavelength separation protocols of interest include, but are not limited to, colored glass, bandpass filters, interference filters, dichroic mirrors, diffraction gratings, monochromators and combinations thereof, among other wavelength separating protocols. In some embodiments, the wavelength separator is an optical filter.

For example, the optical filter may be a bandpass filter having minimum bandwidths ranging from 2 nm to 100 nm, such as from 3 nm to 95 nm, such as from 5 nm to 95 nm, such as from 10 nm to 90 nm, such as from 12 nm to 85 nm, such as from 15 nm to 80 nm and including bandpass filters having minimum bandwidths ranging from 20 nm to 50 nm.

Methods in certain embodiment also include data acquisition, analysis and recording, such as with a computer, wherein multiple data channels record data from each detector for the light scatter and fluorescence emitted by each particle as it passes through the sample interrogation region of a particle sorting component. In these embodiments, analysis includes classifying and counting particles such that each particle is present as a set of digitized parameter values. The subject systems may be set to trigger on a selected parameter in order to distinguish the particles of interest from background and noise. “Trigger” refers to a preset threshold for detection of a parameter and may be used as a means for detecting passage of a particle through the light source. Detection of an event that exceeds the threshold for the selected parameter triggers acquisition of light scatter and fluorescence data for the particle. Data is not acquired for particles or other components in the medium being assayed which cause a response below the threshold. The trigger parameter may be the detection of forward scattered light caused by passage of a particle through the light beam. The flow cytometer then detects and collects the light scatter and fluorescence data for the particle.

A particular subpopulation of interest is then further analyzed by “gating” based on the data collected for the entire population. To select an appropriate gate, the data is plotted so as to obtain the best separation of subpopulations possible. This procedure may be performed by plotting forward light scatter (FSC) vs. side (i.e., orthogonal) light scatter (SSC) on a two dimensional dot plot. A subpopulation of particles is then selected (i.e., those cells within the gate) and particles that are not within the gate are excluded. Where desired, the gate may be selected by drawing a line around the desired subpopulation using a cursor on a computer screen. Only those particles within the gate are then further analyzed by plotting the other parameters for these particles, such as fluorescence. Where desired, the above analysis may be configured to yield counts of the particles of interest in the sample.

In certain embodiments, the system operates to determine a timeslot during which one or more containers at a distal end of a particle sorting component are aligned with the deflected droplet receiving location. In some instances, the deflection signal includes an initial deflection sub-signal and a final deflection sub-signal; and the system operates to produce the deflection signal by sending an initial deflection sub-signal at the beginning of the timeslot that configures the deflector to deflect an analyzed droplet, when present. In certain cases, methods include sending a final deflection sub-signal to the particle sorting component at the end of the timeslot that configures the deflector not to deflect an analyzed droplet. In some embodiments, methods include sending a final deflection sub-signal to the particle sorting component after a single analyzed droplet has been deflected during the timeslot, where the final deflection sub-signal configures the deflector not to deflect an analyzed droplet.

### Kits

Aspects of the invention further include kits, where kits include one or more lasers, such as one or more diode lasers, a thermoelectric cooler and a heat dissipation component as described herein. Kits may also include an optical deck substrate, such as a printed circuit board as well as mounting pads for positioning on a bottom surface of the heat dissipation component. Optical adjustment components such as lenses, beam shaping optics, collimators as well as power meters for measuring laser beam intensity may also be included in the kits. In certain embodiments, kits include a laser that consists of a laser diode and a collimating lens.

The various components of the kits may be present in separate containers, or some or all of them may be pre-combined. For example, in some instances, one or more components of the kit, e.g., laser diode, thermoelectric cooler, heat transfer block, heat dissipation fins are present in a sealed pouch, e.g., a sterile foil pouch or envelope.

In addition to the above components, the subject kits may further include (in certain embodiments) instructions for practicing the subject methods. These instructions may be present in the subject kits in a variety of forms, one or more of which may be present in the kit. One form in which these instructions may be present is as printed information on a suitable medium or substrate, e.g., a piece or pieces of paper on which the information is printed, in the packaging of the kit, in a package insert, and the like. Yet another form of these instructions is a computer readable medium, e.g., diskette, compact disk (CD), portable flash drive, and the like, on which the information has been recorded. Yet another form of these instructions that may be present is a website address which may be used via the internet to access the information at a removed site.

### Utility

The subject laser assemblies find use in a variety of applications where it is desirable to analyze and sort particle components in a sample in a fluid medium, such as a biological sample. Laser assemblies, e.g., as described herein, also find use in flow cytometry where it is desirable to provide a flow cytometer with improved cell sorting accuracy, enhanced particle collection, reduced energy consumption, particle charging efficiency, more accurate particle charging and enhanced particle deflection during cell sorting.

Laser assemblies, e.g., as described herein, also find use in applications where cells prepared from a biological sample may be desired for research, laboratory testing or for use in therapy. In some embodiments, the subject methods and devices may facilitate the obtaining individual cells prepared from a target fluidic or tissue biological sample. For example, the subject methods and systems facilitate obtaining cells from fluidic or tissue samples to be used as a research or diagnostic specimen for diseases such as cancer. Likewise, the subject methods and systems facilitate obtaining cells from fluidic or tissue samples to be used in therapy. Methods and devices of the present disclosure allow for separating and collecting cells from a biological sample (e.g., organ, tissue, tissue fragment, fluid) with enhanced efficiency and low cost as compared to traditional flow cytometry systems.

Notwithstanding the appended claims, the disclosure is also defined by the following clauses:

1. A laser assembly comprising:

a laser;

a thermoelectric cooler in contact with a bottom surface of the laser; and

a heat dissipation component in contact with a bottom surface of the thermoelectric cooler.

2. The laser assembly according to clause 1, wherein the laser is a diode laser.
3. The laser assembly according to any of clauses 1-2, wherein the thermoelectric cooler is a Peltier thermoelectric cooler.
4. The laser assembly according to any of clauses 1-3, wherein the heat dissipation component further comprises a heat dissipation fin.
5. The laser assembly according to clause 4, wherein the heat dissipation component comprises a plurality of heat dissipation fins.
6. The laser assembly according to any of clauses 1-5, wherein the heat dissipation component comprises a first heat transfer block and a second heat transfer block.
7. The laser assembly according to clause 6, wherein the heat dissipation component is configured to symmetrically dissipate heat from the thermoelectric cooler to the first heat transfer block and the second heat transfer block.
8. The laser assembly according to any of clauses 6-7, wherein the heat dissipation component is symmetrical across a vertical plane.
9. The laser assembly according to any of clauses 6-8, wherein the first heat transfer block and the second heat transfer block comprise a plurality of heat dissipation fins.
10. The laser assembly according to any of clauses 1-8, wherein the heat dissipation component is axially symmetrical.
11. The laser assembly according to any of clauses 1-9, wherein the heat dissipation component comprises one or more cutouts.
12. The laser assembly according to clause 10, wherein the one or more cutouts are configured to dissipate heat by thermal expansion.
13. The laser assembly according to any of clauses 1-12, further comprising one or more thermally insulating mounting pads in contact with a bottom surface of the heat dissipation component.
14. The laser assembly according to any of clauses 1-13, wherein the heat dissipation component comprises a ceramic.
15. The laser assembly according to any of clauses 1-13, wherein the heat dissipation component comprises a metal.
16. The laser assembly according to any of clauses 1-15, wherein the laser consists of a laser diode and a collimating lens.
17. An optical deck comprising:

a substrate; and

a laser assembly in contact with a surface of the substrate, the laser assembly comprising:
a laser;
a thermoelectric cooler in contact with a bottom surface of the laser; and
a heat dissipation in contact with a bottom surface of the thermoelectric cooler.
   18. The optical deck according to clause 17, wherein the substrate is a printed circuit board.
   19. The optical deck according to any of clauses 17-18, wherein a bottom surface of the heat dissipation component is molded to the surface of the substrate.
   20. The optical deck according to any of clauses 17-19, wherein the laser assembly further comprises thermally insulating mounting pads on a bottom surface of the heat dissipation component.
   21. The optical deck according to clause 20, wherein the heat dissipation component is in contact with the surface of the substrate through the thermally insulating mounting pads.
   22. The optical deck according to any of clauses 17-21, further comprising an optical adjustment component.
   23. The optical deck according to clause 22, wherein the optical adjustment component comprises beam shaping optics.
   24. The optical deck according to any of clauses 22-23, wherein the optical adjustment component is mounted to the surface of the substrate.
   25. The optical deck according to any of clauses 17-24, further comprising a laser power monitor.
   26. The optical deck according to clause 25, wherein the laser power monitor is mounted to the surface of the substrate.
   27. The optical deck according to any of clauses 17-26, wherein the laser is a diode laser.
   28. The optical deck according to any of clauses 17-27, wherein the thermoelectric cooler is a Peltier thermoelectric cooler.
   29. The optical deck according to any of clauses 17-28, wherein the heat dissipation component further comprises a heat dissipation fin.
   30. The optical deck according to clause 29, wherein the heat dissipation component comprises a plurality of heat dissipation fins.
   31. The optical deck according to any of clauses 17-30, wherein the heat dissipation component comprises a first heat transfer block and a second heat transfer block.
   32. The optical deck according to clause 31, wherein the heat dissipation component is configured to symmetrically dissipate heat from the thermoelectric cooler to the first heat transfer block and the second heat transfer block.
   33. The optical deck according to any of clauses 31-32, wherein the heat dissipation component is symmetrical across a vertical plane.
   34. The optical deck according to any of clauses 31-33, wherein the first heat transfer block and the second heat transfer block comprise a plurality of heat dissipation fins.
   35. The optical deck according to any of clauses 17-34, wherein the heat dissipation component is axially symmetrical.
   36. The optical deck according to any of clauses 17-35, wherein the heat dissipation component comprises one or more cutouts.
   37. The optical deck according to clause 36, wherein the one or more cutouts are configured to dissipate heat by thermal expansion.
   38. The optical deck according to any of clauses 17-37, wherein the heat dissipation component comprises a ceramic.
   39. The optical deck according to any of clauses 17-37, wherein the heat dissipation component comprises a metal.
   40. The optical deck according to any of clauses 17-39, wherein the laser consists of a laser diode and a collimating lens.
   41. A flow cytometer comprising:

a flow cell configured to propagate a sample in a flow stream;

a sensor configured to detect light signals from the flow stream; and

a laser assembly comprising:
a laser configured to irradiate the sample in the flow stream;
a thermoelectric cooler in contact with a bottom surface of the laser; and
a heat dissipation in contact with a bottom surface of the thermoelectric cooler.
   42. The flow cytometer according to clause 41, wherein the laser is a diode laser.
   43. The flow cytometer according to clause 42, wherein the diode laser is selected from the group consisting of an ultraviolet diode laser, a visible diode laser and a near-infrared diode laser.
   44. The flow cytometer according to any of clauses 41-43, wherein the laser assembly is mounted to a surface of a substrate.
   45. The flow cytometer according to clause 44, wherein the substrate is a printed circuit board.
   46. The flow cytometer according to any of clauses 44-45, wherein the heat dissipation component is molded to the surface of the substrate.
   47. The flow cytometer according to any of clauses 41-46, wherein the laser assembly further comprises thermally insulating mounting pads on a bottom surface of the heat dissipation component.
   48. The flow cytometer according to clause 47, wherein the heat dissipation component is in contact with the surface of the substrate through the thermally insulating mounting pads.
   49. The flow cytometer according to any of clauses 41-48, further comprising an optical adjustment component.
   50. The flow cytometer according to clause 49, wherein the optical adjustment component comprises beam shaping optics.
   51. The flow cytometer according to any of clauses 49-50, wherein the optical adjustment component is mounted to the surface of the substrate.
   52. The flow cytometer according to any of clauses 41-51, further comprising a laser power monitor.
   53. The flow cytometer according to clause 52, wherein the laser power monitor is mounted to the surface of the substrate.
   54. The flow cytometer according to any of clauses 41-53, wherein the thermoelectric cooler is a Peltier thermoelectric cooler.
   55. The flow cytometer according to any of clauses 41-54, wherein the heat dissipation component further comprises a heat dissipation fin.
   56. The flow cytometer according to clause 55, wherein the heat dissipation component comprises a plurality of heat dissipation fins.
   57. The flow cytometer according to any of clauses 41-56, wherein the heat dissipation component comprises a first heat transfer block and a second heat transfer block.
   58. The flow cytometer according to clause 57, wherein the heat dissipation component is configured to symmetrically dissipate heat from the thermoelectric cooler to the first heat transfer block and the second heat transfer block.
   59. The flow cytometer according to any of clauses 57-58, wherein the heat dissipation component is symmetrical across a vertical plane.
   60. The flow cytometer according to any of clauses 57-59, wherein the first heat transfer block and the second heat transfer block comprise a plurality of heat dissipation fins.
   61. The flow cytometer according to any of clauses 41-60, wherein the heat dissipation component is axially symmetrical.
   62. The flow cytometer according to any of clauses 41-61, wherein the heat dissipation component comprises one or more cutouts.
   63. The flow cytometer according to clause 62, wherein the one or more cutouts are configured to dissipate heat by thermal expansion.
   64. The flow cytometer according to any of clauses 41-63, wherein the heat dissipation component comprises a ceramic.
   65. The flow cytometer according to any of clauses 41-63, wherein the heat dissipation component comprises a metal.
   66. The flow cytometer according to any of clauses 41-65, wherein the laser consists of a laser diode and a collimating lens.
   67. A method comprising:

irradiating a sample in a flow stream with a laser assembly, the laser assembly comprising:
a laser configured to irradiate the sample in the flow stream;
a thermoelectric cooler in contact with a bottom surface of the laser; and
a heat dissipation component in contact with a bottom surface of the thermoelectric cooler; and

detecting light from the flow stream at one or more wavelengths.

68. The method according to clause 67, wherein the laser is a diode laser.
69. The method according to any of clauses 67-68, wherein the flow stream is irradiated with the laser at a wavelength from 200 nm to 800 nm.
70. The method according to any of clauses 67-69, wherein the laser assembly is mounted to a surface of a substrate.
71. The method according to clause 70, wherein the substrate is a printed circuit board.
72. The method according to any of clauses 70-71, wherein the heat dissipation component is molded to the surface of the substrate.
73. The method according to any of clauses 67-72, wherein the laser assembly further comprises thermally insulating mounting pads on a bottom surface of the heat dissipation component.
74. The method according to clause 73, wherein the heat dissipation component is in contact with the surface of the substrate through the thermally insulating mounting pads.
75. The method according to any of clauses 67-74, further comprising an optical adjustment component.
76. The method according to clause 75, wherein the optical adjustment component comprises beam shaping optics.
77. The method according to any of clauses 75-76, wherein the optical adjustment component is mounted to the surface of the substrate.
78. The method according to any of clauses 67-77, further comprising a laser power monitor.
79. The method according to clause 78, wherein the laser power monitor is mounted to the surface of the substrate.
80. The method according to any of clauses 67-79, wherein the thermoelectric cooler is a Peltier thermoelectric cooler.
81. The method according to any of clauses 67-80, wherein the heat dissipation component further comprises a heat dissipation fin.
82. The method according to clause 81, wherein the heat dissipation component comprises a plurality of heat dissipation fins.
83. The method according to any of clauses 67-82, wherein the heat dissipation component comprises a first heat transfer block and a second heat transfer block.
84. The method according to clause 83, wherein the heat dissipation component is configured to symmetrically dissipate heat from the thermoelectric cooler to the first heat transfer block and the second heat transfer block.
85. The method according to any of clauses 83-84, wherein the heat dissipation component is symmetrical across a vertical plane.
86. The method according to any of clauses 83-85, wherein the first heat transfer block and the second heat transfer block comprise a plurality of heat dissipation fins.
87. The method according to any of clauses 67-86, wherein the heat dissipation component is axially symmetrical.
88. The method according to any of clauses 67-86, wherein the heat dissipation component comprises one or more cutouts.
89. The method according to clause 88, wherein the one or more cutouts are configured to dissipate heat by thermal expansion.
90. The method according to any of clauses 67-89, wherein the heat dissipation component comprises a ceramic.
91. The method according to any of clauses 67-89, wherein the heat dissipation component comprises a metal.
92. The method according to any of clauses 67-91, wherein the laser consists of a laser diode and a collimating lens.
93. The method according to any one of clauses 67-92, wherein detecting comprises detecting one or more of forward scattered light, side scattered light, transmitted light and emitted light from the flow stream at one or more wavelengths.
94. The method according to any one of clauses 67-93, further comprising measuring the light from the flow stream at one or more wavelengths.
95. The method according to clause 94, wherein light from the flow stream is measured at wavelengths of from 200 nm to 1200 nm. 96. The method according to clause 95, wherein light from the flow stream is measured at one or more wavelengths selected from the group consisting of 450 nm, 518 nm, 519 nm, 561 nm, 578 nm, 605 nm, 607 nm, 625 nm, 650 nm, 660 nm, 667 nm, 670 nm, 668 nm, 695 nm, 710 nm, 723 nm, 780 nm, 785 nm, 647 nm, 617 nm and a combination thereof.
97. The method according to clause 94, wherein measuring light from the flow stream comprises generating a spectrum of the light from 200 nm to 1000 nm.
98. The method according to any of clauses 67-97, further comprising sorting particles in the sample into two or more sample collection containers in response to the detected light.
99. The method according to clause 98, wherein the particles are sorted into the containers with a droplet deflector configured to apply a deflection force to droplets of the flow stream.
100. The method according to any of clauses 67-99, further comprising preparing the sample for irradiating with the laser, wherein preparing comprises contacting a specimen with one or more reagents.
101. The method according to clause 100, wherein the specimen is a biological tissue sample or a biological fluid.
102. The method according to any of clauses 100-101, further comprising mixing the one or more reagents with the specimen.
103. The method according to clause 102, further comprising contacting the specimen with a buffer solution.
104. A kit comprising:

a diode laser;

a thermoelectric cooler; and

a heat dissipation component,

wherein the thermoelectric cooler is configured to be mounted in contact with a bottom surface of the diode laser and the heat dissipation component is configured to be mounted in contact with a bottom surface of the thermoelectric cooler.

105. The kit according to clause 104, further comprising a substrate configured for coupling to a bottom surface of the heat dissipation component.
106. The kit according to clause 105, wherein the substrate is a printed circuit board.
107. The kit according to any of clauses 104-106, further comprising an optical adjustment component.
108. The kit according to clause 107, wherein the optical adjustment component comprises beam shaping optics.
109. The kit according to any of clauses 105-108, further comprising a thermally insulating mounting pad for mounting a bottom surface of the heat dissipation component to the substrate.
110. The kit according to any of clauses 104-109, wherein the laser consists of a laser diode and a collimating lens.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. Moreover, nothing disclosed herein is intended to be dedicated to the public regardless of whether such disclosure is explicitly recited in the claims.

The scope of the present invention, therefore, is not intended to be limited to the exemplary embodiments shown and described herein. Rather, the scope and spirit of present invention is embodied by the appended claims. In the claims, 35 U.S.C. § 112(f) or 35 U.S.C. § 112(6) is expressly defined as being invoked for a limitation in the claim only when the exact phrase “means for” or the exact phrase “step for” is recited at the beginning of such limitation in the claim; if such exact phrase is not used in a limitation in the claim, then 35 U.S.C. § 112 (f) or 35 U.S.C. § 112(6) is not invoked.

1. A laser assembly comprising:
a laser;
a thermoelectric cooler in contact with a bottom surface of the laser; and
a heat dissipation component in contact with a bottom surface of the thermoelectric cooler.

2. The laser assembly according to claim 1, wherein the laser is a diode laser.

3. The laser assembly according to claim 1, wherein the thermoelectric cooler is a Peltier thermoelectric cooler.

4. The laser assembly according to claim 1, wherein the heat dissipation component further comprises a heat dissipation fin.

5. The laser assembly according to claim 4, wherein the heat dissipation component comprises a plurality of heat dissipation fins.

6. The laser assembly according to claim 1, wherein the heat dissipation component comprises a first heat transfer block and a second heat transfer block.

7. The laser assembly according to claim 6, wherein the heat dissipation component is configured to symmetrically dissipate heat from the thermoelectric cooler to the first heat transfer block and the second heat transfer block.

8. The laser assembly according to claim 6, wherein the heat dissipation component is symmetrical across a vertical plane.

9. The laser assembly according to claim 6, wherein the first heat transfer block and the second heat transfer block comprise a plurality of heat dissipation fins.

10. The laser assembly according to claim 1, wherein the heat dissipation component is axially symmetrical.

11. The laser assembly according to claim 1, wherein the heat dissipation component comprises one or more cutouts.

12. The laser assembly according to claim 10, wherein the one or more cutouts are configured to dissipate heat by thermal expansion.

13. The laser assembly according to claim 1, further comprising one or more thermally insulating mounting pads in contact with a bottom surface of the heat dissipation component.

14-15. (canceled)

16. The laser assembly according to claim 1, wherein the laser consists of a laser diode and a collimating lens.

17. An optical deck comprising:
a substrate; and
a laser assembly in contact with a surface of the substrate, the laser assembly comprising:
a laser;
a thermoelectric cooler in contact with a bottom surface of the laser; and
a heat dissipation in contact with a bottom surface of the thermoelectric cooler.

18. The optical deck according to claim 17, wherein the substrate is a printed circuit board.

19-40. (canceled)

41. A flow cytometer comprising:
a flow cell configured to propagate a sample in a flow stream;
a sensor configured to detect light signals from the flow stream; and
a laser assembly comprising:
a laser configured to irradiate the sample in the flow stream;
a thermoelectric cooler in contact with a bottom surface of the laser; and
a heat dissipation in contact with a bottom surface of the thermoelectric cooler.

42. The flow cytometer according to claim 41, wherein the laser is a diode laser.

43-66. (canceled)

67. A method comprising:
irradiating a sample in a flow stream with a laser assembly according to claim 1,
and
detecting light from the flow stream at one or more wavelengths.

68. The method according to claim 67, wherein the laser is a diode laser.

69-110. (canceled)
